(19) United States
(12) Patent Application Publication
(10) Pub. No.: US 2004/0145377 A1
(43) Pub. Date: Jul. 29, 2004

(54) Linear position sensor utilizing time domain reflectometry

(76) Inventors: Wayne Sherrard, Edmonton (CA); Greg McGillis, Stony Plain (CA)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 10/759,456

(22) Filed: Jan. 16, 2004

(30) Foreign Application Priority Data
Jan. 17, 2003 (CA) 2,416,623

(51) Int. Cl. G01R 27/04; G01R 27/32

(52) U.S. Cl. 324/644

(57) ABSTRACT

A linear position sensor using time domain reflectometry (TDR) includes a rigid linear guide having a first end and a second end. The linear guide is made of a conductive material. A follower is provided having a central aperture. The follower is positioned with the linear guide passing through the central aperture. The follower is of a material that is influenced by a magnet. A TDR instrument is positioned at one end of the linear guide. The TDR instrument is adapted to send a TDR signal parallel to the linear guide which is directed at the follower. The TDR instrument receives a return signal reflected from the follower which indicates the linear positioning of the follower. At least one magnet is provided which is adapted for mounting on an object. The follower is magnetically attracted to or repulsed by the magnet to such an extent that the follower follows the movement of the magnet, thereby indicating the positioning of the object.

### FIELD OF THE INVENTION

The present invention relates to a position sensor that uses time domain reflectometry to determine a linear position of an object.

### BACKGROUND OF THE INVENTION

Position sensors exist that use time domain reflectometry (TDR) to determine a linear position of an object. An example of such a position sensor is U.S. Pat. No. 6,018,247 (Kelly 2000). The Kelly reference discloses a linear position sensing system having a transmission line with a helically wound inductor and ground conductor. A movable member electrically connects with the ground conductor and extends along the helically wound inductor and from a remote end of the helically wound inductor a distance that depends on the position of an object whose position is being determined. A liquid level sensing version utilizes a float at a remote end of the movable member which floats on liquid within a vessel.

### SUMMARY OF THE INVENTION

The present invention relates to an alternative configuration of linear position sensor that uses time domain reflectometry.

According to one aspect of the present invention there is provided a linear position sensor which includes a rigid linear guide having a first end and a second end. The linear guide is made of a conductive material. A follower is provided having a central aperture. The follower is positioned with the linear guide passing through the central aperture. The follower is of a material that is attracted to a magnet. The follower may also be a magnetic follower. A TDR instrument is positioned at one end of the linear guide. The TDR instrument is adapted to send a TDR signal parallel to the linear guide which is directed at the follower. The TDR instrument receives a return signal reflected from the follower which indicates the linear positioning of the follower. At least one magnet is provided which is adapted for mounting on an object. The follower is magnetically attracted to the magnet to such an extent that the follower follows the movement of the magnet. If the follower is a magnetic follower, the follower may also be oriented such that it is magnetically repulsed by the magnet to such an extent that the follower follows the movement of the magnet. The linear positioning of the follower provides an accurate indication of the linear positioning of the magnet mounted to the object.

According to another aspect of the invention there is provided a method of linear position sensing of an object using TDR. A first step involves mounting the rigid linear guide immediately adjacent and parallel to a linear path along which an object travels. The linear guide has a first end, a second end, and is made of a conductive material. A second step involves providing a follower of magnetic material having a central aperture and positioning the follower with the linear guide passing through the central aperture. A third step involves positioning a TDR instrument at one end of the linear guide. The TDR instrument is adapted to send a TDR signal parallel to the linear guide which is directed at the follower. The TDR instrument receives a return signal reflected due to impedance changes caused by the follower which indicates the linear positioning of the follower. A fourth step involves mounting at least one magnet on the object. The follower is magnetically attracted to the magnet to such an extent that the follower follows the movement of the magnet. If the follower is a magnetic follower, the follower also may be oriented such that it is magnetically repulsed by the magnet to such an extent that the follower follows the movement of the magnet. The linear positioning of the follower provides an accurate indication of the linear positioning of the magnet mounted to the object.

It is preferred that the follower be annular, and the embodiments which will hereinafter be illustrated and described use an annular follower. However, the follower need not be annular. An annular shape is preferred merely because it is balanced and has no protruding edges that could get caught and adversely affect its axial movement between the first end and the second end of the linear guide.

Beneficial results have been obtained through the use of a metal rod or a tensioned metal cable as the linear guide. The linear guide could take other forms.

The linear position sensor is intended to function with the linear guide in a vertical orientation and the embodiments which will hereinafter be illustrated and described contemplate such a vertical orientation. It is possible for the linear guide to function in a horizontal or angular orientation. However, in such applications, measures will have to be taken to minimize friction between the linear guide and the follower. This could be addressed through the use of a metal rod to which is applied graphite or some other form of lubricating substance. The follower may also have a low friction coating.

Although beneficial results may be obtained through the use of the linear position sensor, as described above, it is contemplated that in most applications it will be desirable to protect the follower and the linear guide from environmental factors. Even more beneficial results may, therefore, be obtained when a protective tubular housing overlies the linear guide with follower. The tubular housing has an interior bore sized to allow unfettered axial movement of the follower along the linear guide.

It is preferred that the housing be conductive. If the housing is not conductive, the free space signal will result in a relatively weak reflection. With a conductive housing, the reflection is much stronger and easier to detect.

A number of applications will hereinafter be further described. In one application the object is a liquid level indicator mounted to an exterior of a liquid storage tank. In another application, the object is a fluid level indicator adapted to float on top of one of a liquid or a gas in a fluid storage tank. When the object is a float, the float can be made to encircle the tubular housing.

It is preferred that the system facilitate remote monitoring. It is, therefore, preferred that the TDR instrument is connected to a communications link to allow remote monitoring of the position of the object.

### BRIEF DESCRIPTION OF THE DRAWINGS

These and other features of the invention will become more apparent from the following description in which reference is made to the appended drawings, the drawings are for the purpose of illustration only and are not intended to in any way limit the scope of the invention to the particular embodiment or embodiments shown, wherein:

FIG. 1 is a linear position sensor utilizing time domain reflectometry constructed in accordance with the teachings of the present invention in use with a liquid level indicator mounted to an exterior of a liquid storage tank.

FIG. 2 is a linear position sensor utilizing time domain reflectometry constructed in accordance with the teachings of the present invention in use with a float floating on top of a liquid in a liquid storage tank.

FIG. 3 is a linear position sensor utilizing time domain reflectometry constructed in accordance with the teachings of the present invention in use with a float floating on top of liquefied gas in a liquefied gas storage tank.

FIG. 4 is a linear position sensor utilizing time domain reflectometry and magnetic repulsion in use with a liquid level indicator mounted to an exterior of a liquid storage tank in vertical orientation.

### DETAILED DESCRIPTION OF THE PREFERRED EMBODIMENT

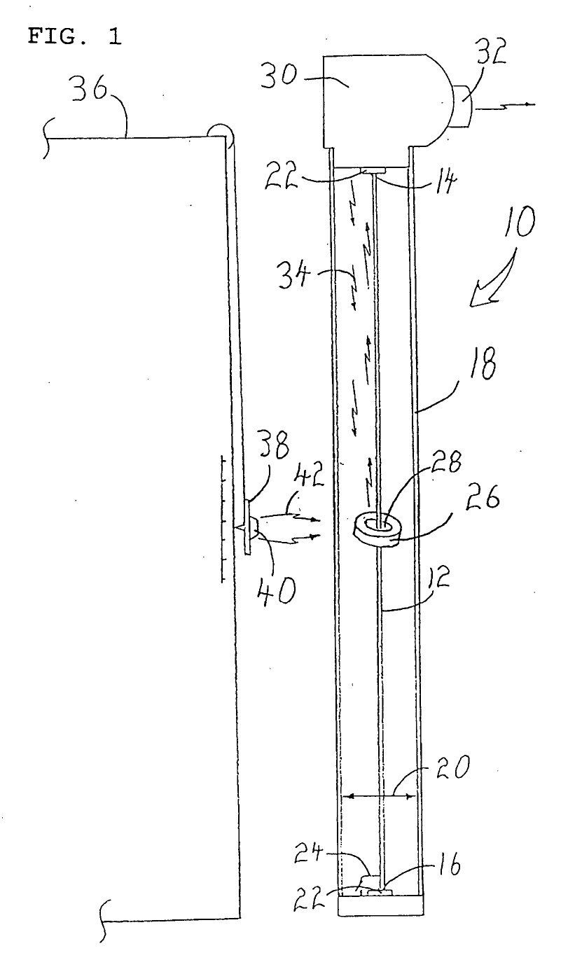

The preferred embodiment, a linear position sensor utilizing time domain reflectometry generally identified by reference numeral 10, will now be described in use in several different environments with reference to FIGS. 1 through 3.

Basic Structure:

Referring to FIG. 1, linear position sensor 10 includes a rigid linear guide 12 having a first end 14 and a second end 16. Linear guide 12 can take various forms. Beneficial results have been obtained through the use of a metal rod or a tensioned metal cable. Linear guide 12 is positioned in a vertical orientation within a tubular housing 18. Tubular housing 18 has an interior bore 20. It will be understood that the ratio of the interior diameter of tubular housing 18 to the outer diameter of linear guide 12 determines TDR characteristic impedance values. First end 14 is adapted with electronically isolating material 22. Second end 16 has grounding 24 to tubular housing 18 or, selectively, electronically isolating material 22. An annular follower 26 having a central aperture 28 is positioned with linear guide 12 passing in loose tolerance through central aperture 28. Annular follower 26 is also in loose tolerance within bore 20 of tubular housing 18. A TDR instrument 30, adapted with a communications link 32, is positioned at first end 14 of linear guide 12. TDR instrument 30 is adapted to direct a TDR signal 34 at annular follower 26. TDR signal 34 is consequently reflected back to TDR instrument 30 from annular follower 26 due to characteristic impedance changes. The signal is processed and the information is then transmitted via communications link 32.

There will now be described how linear position sensor 10 is integrated into different environments:

When used to track a liquid level indicator mounted to an exterior of a liquid storage tank:

Structure and Relationship of Parts:

Referring to FIG. 1, in the illustrated embodiment, a liquid storage tank 36 is provided having a liquid level indicator 38. Linear position sensor 10 is positioned adjacent to and parallel to liquid storage tank 36 and liquid level indicator 38. Liquid level indicator 38 is modified by the addition of one or more magnets 40. Magnet 40 exerts magnetic force, shown by force lines 42, on annular follower 26. The magnetic attraction or repulsion is such that annular follower 26 adopts the same linear position relative to liquid storage tank 36 as liquid level indicator 38.

Operation:

The use and operation of linear position sensor 10 when used to track a liquid level indicator mounted to an exterior of a liquid storage tank will now be described with reference to FIG. 1. As the amount of liquid in liquid storage tank 36 varies, liquid level indicator 38 follows the variations and visually indicates the liquid level on the side of liquid storage tank 36. Magnet 40 creates a master slave relationship between liquid level indicator 38 and annular follower 26 of linear position sensor 10. The travel of annular follower 26 tracks the travel of liquid level indicator 38. It is, of course, important that linear position sensor be positioned close enough to liquid level indicator 38 to enable magnet 40 to act upon annular follower 26. It is desirable, but not essential, to isolate the operation of linear position sensor 10 from environmental factors by enclosing rigid linear guide 12 and annular follower 26 within tubular housing 18. This option is illustrated. Upon activation of TDR instrument 30, TDR signals 34 are projected towards annular follower 26 and reflected back to TDR instrument 30. As magnetic force 42 is exerted on annular follower 26, annular follower 26 moves along rigid linear guide 12, changing the distance between itself and TDR instrument 30. The interpretation of the variations in distance and time it takes the signals to travel to annular follower 26 and back is processed and becomes the measurement data. The position of annular follower 26 is interpreted by TDR instrument 30 as reflecting a given liquid level and the resulting information is transmitted via communications link 32 to a remote operator monitoring liquid storage tank 36.

When used to track a float in a liquid storage tank:

Structure and Relationship of Parts:

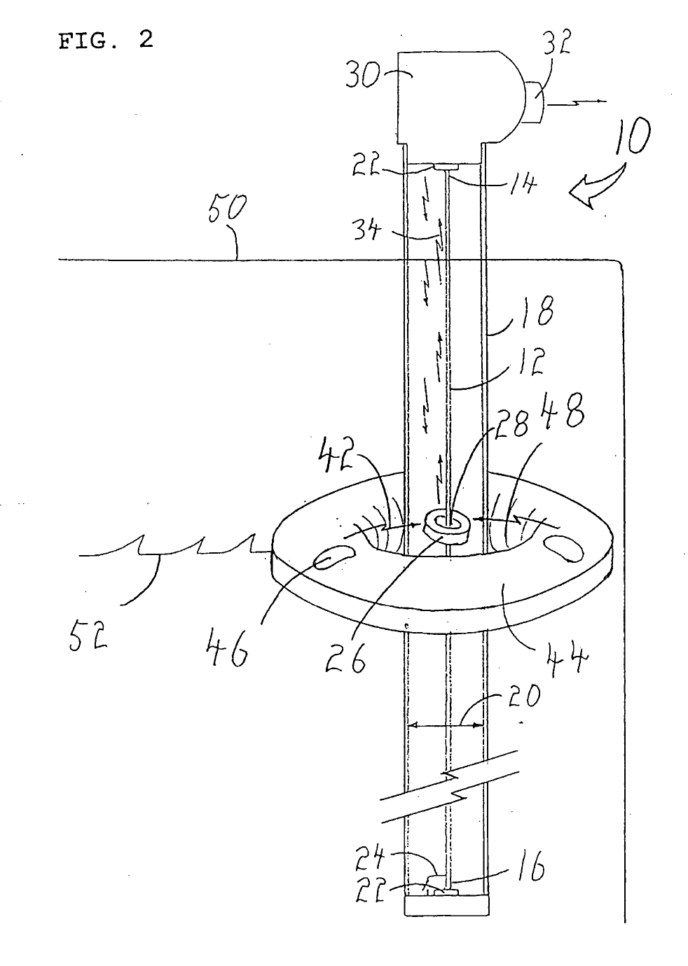

Referring to FIG. 2, a float 44 having at least one embedded magnet 46 and a second aperture 48 is positioned such that tubular housing 18 passes directly through second aperture 48. Tubular housing 18 of linear position sensor 10 is positioned directly in second liquid storage tank 50. Float 44 floats on liquid surface 52. One or more embedded magnets 46 exert a magnetic force, as indicated by force lines 42, on annular follower 26 such that annular follower 26 adopts the same linear position as liquid surface 52.

Operation:

The use and operation of linear position sensor 10 when used to track a float in a liquid storage tank will now be described with reference to FIG. 2. As the amount of liquid in second liquid storage tank 50 varies, float 44 follows the variations by floating on liquid surface 52. Magnet 46 creates a master slave relationship between float 44 and annular follower 26. Linear position sensor 10 is positioned directly within liquid storage tank 50 and is in close proximity to float 44 as it passes directly through second aperture 48 of float 44. Since the environmental factors in this application are likely incompatible to the operation of linear position sensor 10, rigid linear guide 12 and annular follower 26 are illustrated enclosed and sealed in tubular housing 18. Upon activation of TDR instrument 30, the continued use and operation of linear position sensor 10 in the present environment is the same as in the previous environment as embedded magnet 46 on float 44 exerts magnetic force 42 on annular follower 26 causing it to change position. The position of annular follower 26 is interpreted by TDR instrument 30 as reflecting a given liquid level and the resulting information is transmitted via communications link 32 to a remote operator monitoring liquid storage tank 50.

When used to track a float in a liquid or in a gas pressurised to the point of liquefaction in a storage tank:

Structure and Relationship of Parts:

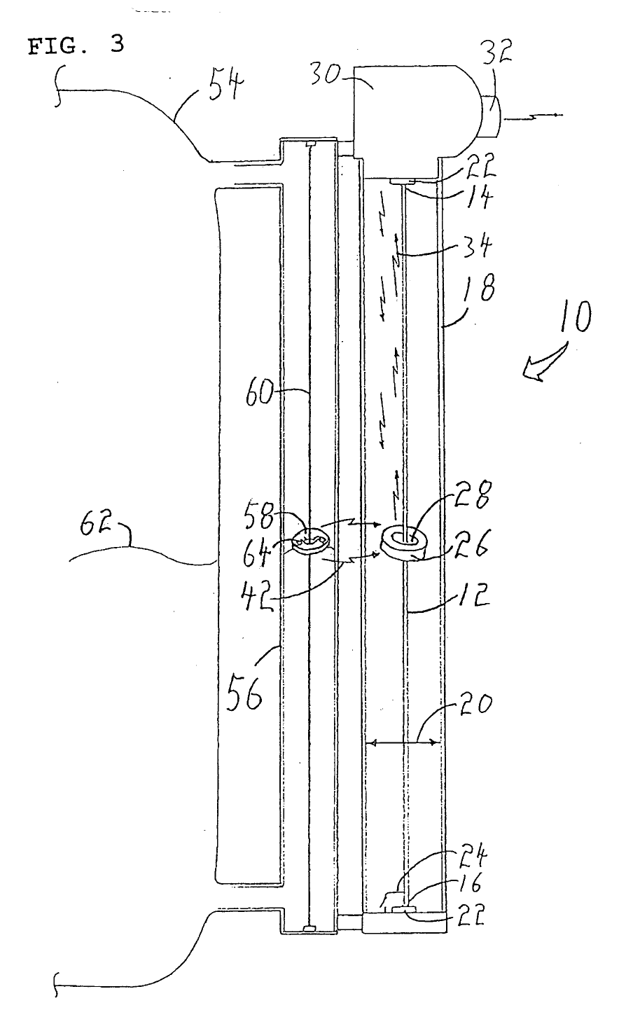

Referring to FIG. 3, a tank 54 is provided having a fitting 56 adapted with a second float 58 and rigid positioner 60. Second float 58 positions itself on surface 62 of liquefied gas. Linear position sensor 10 is positioned adjacent to tank 54 and parallel to fitting 56. Second float 58 is adapted with one or more second embedded magnet 64. Second embedded magnet 64 exerts magnetic force 42 on annular follower 26 such that annular follower 26 adopts the same linear position relative to tank 54 as second float 58.

Operation:

The use and operation of linear position sensor 10 when used to track a float in a liquefied gas storage tank will now be described with reference to FIG. 3. It will be understood that this description also applies to a liquid storage tank. As the amount of liquefied gas in tank 54 varies, second float 58 follows the variations by floating on surface 62. Second embedded magnet 64 creates a master slave relationship between second float 58 and annular follower 26. Linear position sensor 10 is positioned so that the travel of annular follower 26 along rigid linear guide 12 is adjacent and parallel to the travel of second float 58. In order to isolate operation from environmental factors, it is preferred that rigid linear guide 12 and annular follower 26 be enclosed in tubular housing 18. This option is illustrated. Upon activation of TDR instrument 30, the continued use and operation of linear position sensor 10 in the present environment is the same as in the previous two environments as second embedded magnet 64 on second float 58 exerts magnetic force 42 on annular follower 26 causing it to change position. The position of annular follower 26 is interpreted by TDR instrument 30 as reflecting a given liquid level and the resulting information is transmitted via communications link 32 to a remote operator monitoring storage tank 54.

Comments on Operation:

According to the teachings of the preferred embodiment, tubular housing 18 consists of a metal conductive pipe made of a material such as stainless steel that will allow a magnetic field to pass though it. Rigid linear guide 12 may be a thin cable or rod centered inside tubular housing 18. If it is a cable, it should be under a slight tension to make sure it stays centered. Annular follower 26 is constructed of a material that is attracted to a magnet. This may be magnetic or is a light material with magnetic material embedded in it. The dimensions of annular follower 26 are such that there is ample play or clearance to prevent binding or wedging against tubular housing 18 or rigid linear guide 12. While under the influence of magnet force 42, annular follower 26 is free to move up and down within tubular housing 18 while being constrained and guided by rigid linear guide 12. The inside dimensions of bore 20 and the dimensions of rigid linear guide 12 are selected not only to be physically strong enough for the application, but also to give a known transmission line characteristic impedance for suitable transmission of TDR signal 34 and its reflection. These dimensions would be influenced by the specific TDR instrument 30 used and the characteristic impedance it would work best with. Further, some TDR instruments 30 may need the opposite polarity to operate properly. It is at this point that an operator must determine whether ground 24 should be engaged or not. The use and operation of linear position sensor 10, as previously described in relation to liquefied gas storage tank 54, is similar to any other pressurized tank, but also applies to unpressurized tanks. It will be appreciated that fitting 56 could also be stainless steel or any other appendage to the tank which would house a float apparatus. This allows linear position sensor 10 to be strapped to or otherwise positioned such that TDR instrument 30 can track a float or other object outside of the pressurized environment.

Variations:

Although the examples selected all relate directly or indirectly to the measurement of fluid levels, it will be understood that the teachings of the invention have wide application. Some other applications include: determining the position of large sliding doors or gates; determining sliding damper position in building air handling units; determining piston positions in applications such as garbage crushers; determining hatch positions on bulk carrier ships; and determining lift or single floor elevator positions.

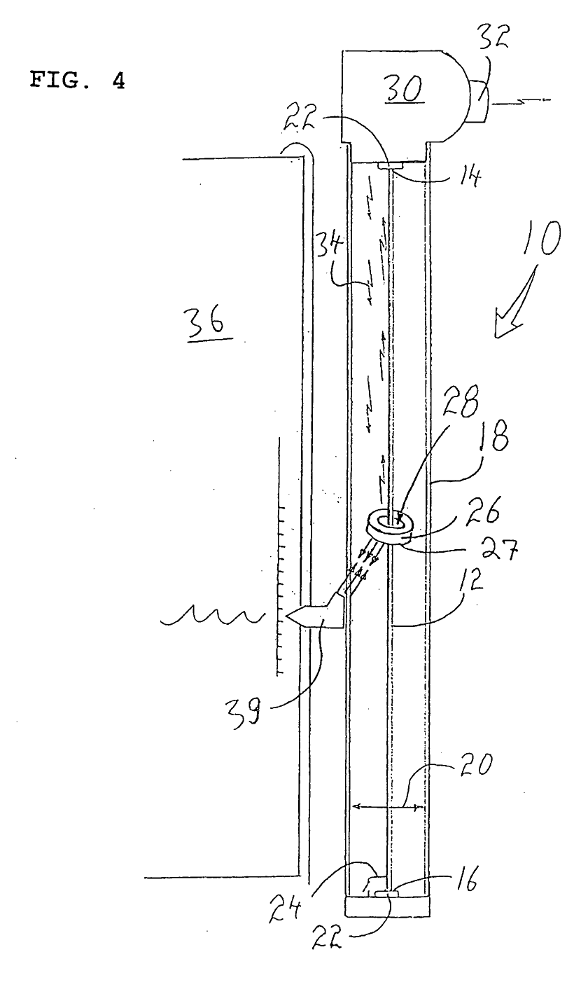

Referring to FIG. 4, the follower 26 may also be a magnetic follower that is magnetically repulsed by magnet 39 that is part of a liquid level indicator. While this variation is shown with respect to a liquid level indicator mounted to the exterior of a liquid storage tank 36, it should be understood that it is adaptable to other situations as well. Magnet 39 is positioned in effective proximity to magnetic follower 26 such that opposed magnetic poles between magnetic follower 26 and magnet 39 (north to north or south to south), repel each other, moving magnetic follower 26 in response to movement of magnet 39. By placing magnetic follower 26 above magnet 39, gravity is used to keep the follower 26 close to the magnet 39 when the magnet 39 is receding, while the repulsion force and gravity work opposite each other such that the follower 26 is kept close when the magnet 39 is rising, and stationary when the magnet 39 is stationary.

Friction can reduce the responsiveness of magnetic follower 26. This is particularly the case in angular or horizontal manifestations of linear position sensor 10. For that reason, magnetic follower 26 is treated with a low friction coating 27, such as TEFLON™, which is suitable because it is relatively inexpensive and easy to shape.

In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be one and only one of the elements.

It will be apparent to one skilled in the art that modifications may be made to the illustrated embodiment without departing from the spirit and scope of the invention as hereinafter defined in the Claims.

The embodiments of the invention in which an exclusive property or privilege is claimed are defined as follows:

1. A linear position sensor, comprising:
a rigid linear guide having a first end, a second end and being made of a conductive material;
a follower having a central aperture, the follower being positioned with the linear guide passing through the central aperture, the follower being of a material that is one of a magnet or subject to influence by a magnet;
a TDR instrument at one end of the linear guide, the TDR instrument being adapted to send a TDR signal parallel to the linear guide which is directed at the follower, the TDR instrument receiving a return signal reflected from the follower which indicates the linear positioning of the follower; and
at least one magnet adapted for mounting on an object, the follower being magnetically influenced through one of attraction or repulsion to the at least one magnet to such an extent that the follower follows the movement of the at least one magnet, whereby the linear positioning of the follower provides an accurate indication of the linear positioning of the at least one magnet mounted to the object.

2. The linear position sensor as defined in claim 1, wherein the follower is of a material that is subject to influence by a magnet and the follower is magnetically attracted to the at least one magnet.

3. The linear position sensor as defined in claim 1, wherein the follower is a magnet and is magnetically attracted to the at least one magnet.

4. The linear position sensor as defined in claim 1, wherein the follower is a magnet and is magnetically repulsed by the at least one magnet.

5. The linear position sensor as defined in claim 1, wherein the follower is annular.

6. The linear position sensor as defined in claim 1, wherein the linear guide is one of a metal rod or a tensioned metal cable.

7. The linear position sensor as defined in claim 1, wherein the linear guide is in a vertical orientation.

8. The linear position sensor as defined in claim 1, wherein a protective tubular housing overlies the linear guide with follower, the tubular housing having an interior bore sized to allow the follower unfettered axial movement of along the linear guide.

9. The linear position sensor as defined in claim 8, wherein the housing is made from a conductive material.

10. The linear position sensor as defined in claim 1, wherein the object is a liquid level indicator mounted to an exterior of a liquid storage tank.

11. The linear position sensor as defined in claim 1, wherein the object is a fluid level indicator adapted to float on top of one of a liquid or a liquefied gas in a fluid storage tank.

12. The linear position sensor as defined in claim 8, wherein the object is a float which surrounds the tubular housing.

13. A linear position sensor, comprising:
a rigid linear guide having a first end, a second end, and being made of a conductive material;
a follower having a central aperture, the follower being positioned with the linear guide passing through the central aperture, the follower being of a material that is attracted to a magnet;
a TDR instrument at one end of the linear guide, the TDR instrument being adapted to send a TDR signal parallel to the linear guide which is directed at the follower, the TDR instrument receiving a return signal reflected from the follower which indicates the linear positioning of the follower;
a fluid impervious protective conductive tubular housing overlies the linear guide with follower, the tubular housing having an interior bore sized to allow the follower unfettered axial movement along the linear guide; and
a float having a central aperture, the float being positioned with the tubular housing passing through the central aperture, the float being adapted to float on liquid and rise and fall along a path defined by the tubular housing, the float having at least one magnet, the follower being magnetically attracted to the at least one magnet to such an extent that the follower follows the movement of the at least one magnet, whereby the linear positioning of the follower provides an accurate indication of the linear positioning of the at least one magnet mounted to the float.

14. A method of linear position sensing of an object using TDR, comprising the steps of:
mounting a rigid linear guide immediately adjacent and parallel to a linear path along which an object travels, the linear guide having a first end, a second end, and being made of a conductive material;
providing a follower having a central aperture and positioning the follower with the linear guide passing through the central aperture, the follower being of a material that is attracted to a magnet;
positioning a TDR instrument at one end of the linear guide, the TDR instrument being adapted to send a TDR signal parallel to the linear guide which is directed at the follower, the TDR instrument receiving a return signal reflected from the follower which indicates the linear positioning of the follower;
mounting at least one magnet on the object, the follower being magnetically attracted to the at least one magnet to such an extent that the follower follows the movement of the at least one magnet, the linear positioning of the follower providing an accurate indication of the linear positioning of the at least one magnet mounted to the object.

15. A linear position sensor, comprising:
a rigid linear guide having a first end, a second end, and being one of a metal rod or a tensioned metal cable, the linear guide being positioned in a vertical orientation;
an annular follower having a central aperture, the follower being positioned with the linear guide passing through the central aperture, the follower being of a material that is attracted to a magnet;
a TDR instrument at one end of the linear guide, the TDR instrument being adapted to send a TDR signal parallel to the linear guide which is directed at the follower, the TDR instrument receiving a return signal reflected from the follower which indicates the linear positioning of the follower;
a protective conductive tubular housing overlying the linear guide with follower, the tubular housing having an interior bore sized to allow the follower unfettered axial movement along the linear guide; and
at least one magnet adapted for mounting on an object, the follower being magnetically attracted to the at least one magnet to such an extent that the follower follows the movement of the at least one magnet, whereby the linear positioning of the follower provides an accurate indication of the linear positioning of the at least one magnet mounted to the object.

16. The linear position sensor as defined in claim 15, wherein the object is a liquid level indicator mounted to an exterior of a tank.

17. The linear position sensor as defined in claim 15, wherein the object is a fluid level indicator adapted to float on top of one of a liquid or a liquefied gas.

18. The linear position sensor as defined in claim 17, wherein the fluid level indicator surrounds the tubular housing.

19. The linear position sensor as defined in claim 15, wherein the TDR instrument is connected to a communications link to allow remote monitoring of the position of the object.

20. A linear position sensor, comprising:
a rigid linear guide having a first end, a second end and being made of a conductive material;
a magnetic follower having a central aperture, the follower being positioned with the linear guide passing through the central aperture, the magnetic follower having opposed magnetic poles;
a TDR instrument at one end of the linear guide, the TDR instrument being adapted to send a TDR signal parallel to the linear guide which is directed at the follower, the TDR instrument receiving a return signal reflected from the follower which indicates the linear positioning of the follower; and
a magnet adapted for mounting on an object, the magnet having opposed magnetic poles, the poles of the follower and the magnet being respectively oriented so that the follower is magnetically repelled by the magnet to such an extent that the follower follows the movement of the magnet, whereby the linear positioning of the follower provides an accurate indication of the linear positioning of the magnet mounted to the object.

21. The linear position sensor as defined in claim 20, wherein the follower is annular.

22. The linear position sensor as defined in claim 20, wherein the linear guide is one of a metal rod or a tensioned metal cable.

23. The linear position sensor as defined in claim 20, wherein the linear guide is in a vertical orientation.

24. The linear position sensor as defined in claim 23, wherein the follower has a low friction coating.
